(19) United States
(12) Patent Application Publication
(10) Pub. No.: US 2026/0343848 A1
(43) Pub. Date: Oct. 29, 2026

(54) MEMORY CELL WITH 3-TERMINALS AND SEMICONDUCTOR MEMORY DEVICE INCLUDING THE SAME

(71) Applicant: SK hynix Inc., Gyeonggi-do (KR)

(72) Inventors: Jae Gil LEE, Gyeonggi-do (KR); Won Tae KOO, Gyeonggi-do (KR); Hyung Dong LEE, Gyeonggi-do (KR)

(21) Appl. No.: 19/312,337

(22) Filed: Aug. 28, 2025

(30) Foreign Application Priority Data
Apr. 28, 2025 (KR) 10-2025-0055313

(51) Int. Cl. H10B 12/00; G11C 5/06; H10D 8/00; H10D 8/60; H10D 62/10; H10W 20/43

(52) U.S. Cl. CPC H10B 12/00; G11C 5/063; H10D 8/411; H10D 8/60; H10D 62/124; H10W 20/43

(57) ABSTRACT

A memory cell of a semiconductor memory device may be connected among a write word line, a read word line and a bit line. The memory cell may include a write transistor, a diode and a read transistor. The write transistor may be connected between the write word line and the bit line. The diode may include an anode and a cathode. The anode of the diode may be connected with the write transistor. The read transistor may be connected between the read word line and the bit line.

### CROSS-REFERENCES TO RELATED APPLICATION

The present application claims priority under 35 U.S.C. § 119(a) to Korean application number 10-2025-0055313, filed on Apr. 28, 2025, which is incorporated herein by reference in its entirety.

### BACKGROUND

### 1. Technical Field

Embodiments of the present disclosure relate generally to electronic devices, and, more particularly, to a memory cell with three terminals (3-terminals) and a semiconductor memory device including the same.

### 2. RELATED ART

A dynamic random-access memory (DRAM) device, which is a representative semiconductor memory device, may include a plurality of memory cells. Conventionally, each of the memory cells may include one transistor as a switch and one capacitor as a storage element. Currently, to improve performance of the DRAM device, new methods of integrating a larger number of memory cells in a limited area and fabricating capacitors with a larger capacity within a limited area are needed.

For example, recently, for reducing the area of the memory cell some have been actively trying to reduce the size of the capacitor or completely omitting the capacitor to make capacitorless memory cells. These efforts are in their infancy and further improvements are needed.

### SUMMARY

According to embodiments of the present disclosure, there may be provided a 3-terminal memory cell including a write transistor, a diode and a read transistor. The write transistor may be connected between a write word line and a bit line. The diode may include an anode connected to the write transistor. The read transistor may be connected between a cathode of the diode, the write word line and the bit line. The gate of the read transistor is connected to the diode.

According to embodiments of the present disclosure, there may be provided a semiconductor memory device. The semiconductor memory device may include a plurality of write word lines, a plurality of read word lines, a plurality of bit lines and a plurality of memory cells. The plurality of word lines may extend in parallel along a first direction. The plurality of read word lines may extend in parallel along a second direction intersected with the first direction. The plurality of bit lines may extend in parallel along the second direction. The plurality of bit lines may be arranged alternately with the plurality of read word lines. The plurality of memory cells may be connected with the plurality of write word lines, the plurality of read word lines and the plurality of bit lines. Each of the memory cells may include a write transistor, a diode and a bit line transistor. The write transistor may be connected to one of the plurality of write word lines and one of the plurality of bit lines. The diode may include an anode connected to the write transistor. The read transistor may be connected to a cathode of the diode, one of the plurality of read word lines and the bit line to which the write transistor may be connected.

According to embodiments of the present disclosure, the write transistor may be configured to transmit, in response to an enable signal on the write word line, a write voltage applied to the bit line as data to the anode of the diode.

According to embodiments of the present disclosure, the read transistor may be configured to transmit an enable signal of the read word line to the bit line, based on data received from the diode.

According to embodiments of the present disclosure, when a voltage level of the anode may be no less than a threshold voltage of the diode than a voltage level of the cathode, the diode may be configured to be turned on.

According to embodiments of the present disclosure, the diode may include at least one of a Schottky barrier diode and a PN diode.

According to example embodiments of the present disclosure, there may be provided a 3-terminal memory cell. The memory cell with the 3-terminals may include an active region, a write transistor and a read transistor, a write word line, a bit line, a diode, a read word line and an interconnection wiring. The write transistor and the read transistor may be integrated in the active region. The write word line may be electrically connected with a gate of the write transistor. The bit line may be connected to a source of the write transistor and a source of the read transistor. The diode may be positioned over the gate of the write transistor. The diode may be electrically connected with the gate of the write transistor. The write word line may be connected with a drain of the write transistor. The interconnection wiring may be connected between the diode and the drain of the write transistor. An anode of the diode may be connected to the drain of the write transistor. A cathode of the diode may be connected to the gate of the read transistor.

According to embodiments of the present disclosure, the active region may have a bar shape having a short axis extending in a first direction and a long axis extending in a second direction perpendicular to the first direction. The gate of the write transistor and the gate of the read transistor may extend parallel along the second direction on the active region. The source of the write transistor and the source of the read transistor may include in common a first junction region formed in the active region between the gate of the write transistor and the gate of the read transistor. The drain of the write transistor may include a second junction region formed in the active region at an outside of the gate of the write transistor. The drain of the read transistor may include a third junction region formed in the active region on an outside of the gate of the read transistor.

According to embodiments of the present disclosure, the diode may be positioned over the gate of the read transistor overlapping with the active region. The interconnection wiring may extend to overlap the active region.

According to embodiments of the present disclosure, the diode may be positioned over the gate of the read transistor withdrawn outwardly of the active region. The interconnection wiring may extend to bypass along a periphery of the active region.

According to embodiments of the present disclosure, the active region may include a first active region in which the write transistors may be integrated, and a second active region arranged facing each other at a set spacing from the first active region and in which the read transistors may be integrated.

According to embodiments of the present disclosure, the gate of the write transistor may be disposed at a center of the first active region. The source of the write transistor may be located in the first active region at one side of the gate of the write transistor. The drain of the write transistor may be located in the first active region at the other side of the gate of the write transistor.

According to embodiments of the present disclosure, the gate of the read transistor may be disposed at a center of the second active region while extending a certain length toward the first active region. The source of the read transistor may be disposed in the second active region at one side of the gate of the read transistor. The drain of the read transistor may be disposed in the second active region at the other side of the gate of the read transistor.

According to embodiments of the present disclosure, the diode may be positioned at end of the gate of the read transistor. A portion of the interconnection wiring may be positioned between the first active region and the second active region.

According to embodiments of the present disclosure, A memory cell with 3-terminals comprises a write transistor, a read transistor, and a diode. The write transistor is connected between a write word line and a bit line. The read transistor is connected between a read word line and the bit line. The diode is connected between the read transistor and the write transistor. An anode of the diode is connected with a drain of the write transistor. A cathode of the diode is connected with a gate of the read transistor.

According to embodiments of the present disclosure, the memory cell may be connected to the write word line, the read word line and the common bit line. The memory cell may include the write transistor connected to the write word line and the common bit line, a read transistor connected to the read word line and the common bit line, and a diode connected between the write transistor and the read transistor.

Thus, even if the write transistor and the read transistor are connected to one common bit line, forward driving of the diode can prevent data loss and fluctuations in the non-selected memory cell, thereby reducing the memory cell area while maintaining stable memory characteristics.

### BRIEF DESCRIPTION OF THE DRAWINGS

The above and another aspects, features and advantages of the embodiments of the present disclosure will be more easily understood from the following detailed description taken in conjunction with the accompanying drawings, in which:

FIG. 1 is a circuit diagram illustrating a 3-terminal memory cell in accordance with embodiments of the present disclosure;

FIG. 2 is a timing diagram illustrating an operation for a 3-terminal memory cell in accordance with embodiments of the present disclosure;

FIG. 3 is a circuit diagram illustrating a semiconductor memory device including memory cells with 3-terminals in accordance with embodiments of the present disclosure;

FIG. 4 is a plan view illustrating a 3-terminal memory cell in accordance with embodiments of the present disclosure;

FIG. 5 is a cross-sectional view taken along a line A-A' in FIG. 4;

FIG. 6 is a plan view illustrating a 3-terminal memory cell in accordance with embodiments of the present disclosure; and

FIGS. 7A and 7B are plan views illustrating a 3-terminal memory cell in accordance with embodiments of the present disclosure.

### DETAILED DESCRIPTION

The advantages and features of the embodiments of the present disclosure, and methods of achieving them, will become apparent upon reference to the embodiments described in detail with reference to the accompanying drawings. The embodiments, however, are not limited to the embodiments disclosed herein but may be embodied in many different forms. These embodiments are provided merely to make the disclosure of the invention complete and to give those of ordinary skill in the art a complete idea of the scope of the embodiments, which is defined by the claims. The dimensions and relative sizes of the layers and regions in the drawings may be exaggerated for clarity of description. Throughout the specification, like reference numerals refer to like components.

As used herein, the term “configured” may refer to a size, shape, material composition, orientation, and arrangement of one or more of at least one structure and at least one apparatus that facilitate operation of one or more of the structure and the apparatus in a predetermined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, “and/or” includes any and all combinations of one or more of the associated listed items.

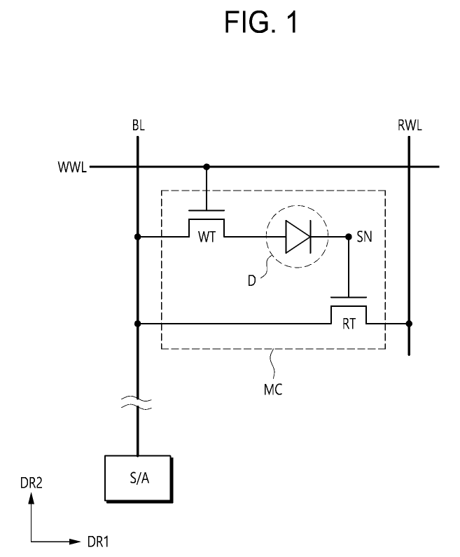

FIG. 1 is a circuit diagram illustrating a 3-terminal memory cell in accordance with embodiments of the present disclosure.

Referring to FIG. 1, a memory cell MC according to some embodiments may have a three-terminal structure connected between a write word line WWL, a read word line RWL and a bit line BL.

For example, the write word line WWL may extend along a first direction DR1. The read word line RWL and the bit line BL may extend parallel to each other. The read word line RWL and the bit line BL may extend along a second direction DR2 that is perpendicular to the first direction DR1.

The memory cell MC with 3-terminals may include a write transistor WT, a read transistor RT and a diode D.

The write transistor WT may include, for example, an NMOS transistor. A gate of the write transistor WT may be connected to the write word line WWL, a source of the write transistor WT may be connected to the bit line BL, and a drain of the write transistor WT may be connected with the diode D.

The read transistor RT may include, for example, an NMOS transistor. A gate of the read transistor RT may be connected to the diode D, a source of the read transistor RT may be connected to the read word line RWL, and a drain of the read transistor RT may be connected with the bit line BL.

According to embodiments of the present disclosure, the write transistor WT and the read transistor RT may include not only NMOS transistors, but also PMOS transistors.

At least one of a channel of the write transistor WT and a channel of the read transistor RT may include a semiconductor material such as silicon (Si) or silicon-germanium (SiGe), an oxide semiconductor material including at least one of IGZO, IGO and In₂O₃, or a two-dimensional material. For example, the two-dimensional material may include at least one of MoS₂, MoSe₂, WS₂, WSe₂, WTe₂, MoTe₂, ZrS₂, ZrSe₂, GaSe, GaTe₂, HfS₂, HfSe₂, SnSe, PtSe₂, PdSe₂, PdTe₂, ReSe₂, VS₂, VSe₂, NbSe₂, FeSe₂ and FeTe₂.

According to embodiments of the present disclosure, the channel of the write transistor WT and the channel of the read transistor RT may include the same material or different materials.

In a case of a memory cell MC with a capacitorless structure, a bandgap of the channel material of the write transistor WT may be larger than a bandgap of the channel material of the read transistor RT so that the data retention time may be increased. In some cases, a structure of the transistor may be changed in addition to adjusting the channel material to provide the read transistor RT with a relatively higher on-current than the write transistor WT. A wider bandgap in the write transistor channel may suppress leakage current, and enhance retention time, while a narrower bandgap or structural modification in the read transistor can improve carrier mobility, enabling higher on-current for faster read access.

The diode D may include, for example, a forward diode. An anode of the diode D may be connected with the write transistor WT. A cathode of the diode D may be connected with the read transistor RT. Accordingly, the diode D may be turned on when a voltage of the anode may be greater than a threshold voltage of the diode D than a voltage of the cathode. Stated differently, the diode D may be turned on when the voltage at the anode exceeds the sum of the threshold voltage of the diode D and the voltage at the cathode. The diode D may be at least one of a rectifier diode, a Schottky diode and a PN diode.

The bit line BL may be connected in common with the drain of the write transistor WT and the drain of the read transistor RT. The memory cell MC according to some embodiments may transmit a write voltage or read (sense) written data via one of the bit lines.

A sense amplifier S/A may be connected to one end of the bit line BL to sense data stored in the selected memory cell MC.

The memory cell MC with the 3-terminals, according to some embodiments, may not include a separate storage element such as a capacitor. The memory cell MC according to some embodiments may use the gate of the read transistor RT as a storage medium. For example, when the memory cell MC is selected, a write voltage provided via the bit line BL may be provided to the gate of the read transistor RT to store data. Furthermore, the memory cell MC with the 3-terminals according to some embodiments may perform memory operations with only the write word line WWL, the read word line RWL and the bit line BL. Therefore, compared to a conventional capacitorless memory cell, the number of the bit lines may be reduced to greatly improve an integration density of the memory device.

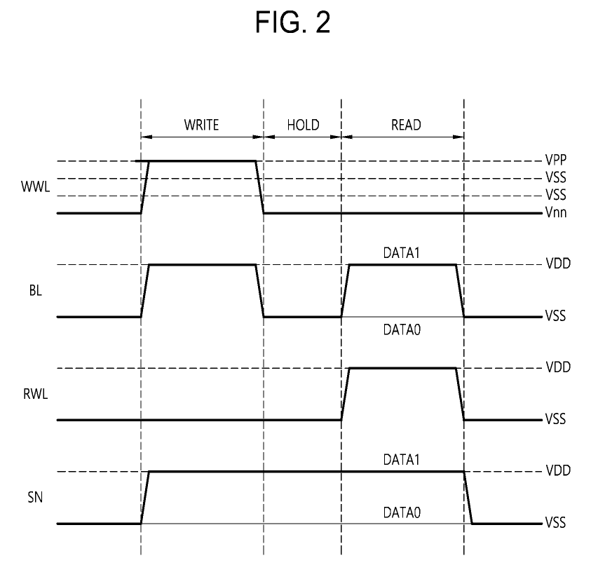

FIG. 2 is a timing diagram illustrating an operation for a 3-terminal memory cell in accordance with embodiments of the present disclosure.

### Write Operation

Referring to FIGS. 1 and 2, when data "1" is to be stored in the memory cell MC, the write word line WWL may be enabled to a VPP voltage level, the bit line BL may be enabled to a VDD voltage level, and the read word line RWL may be disabled to a VSS voltage level. Then, the write transistor WT may be turned on, allowing the VDD voltage provided on the bit line BL to be transferred to the anode of the diode D.

When the VDD voltage is applied to the anode of the diode D, a voltage difference between the anode and the cathode of the diode D may become no less than the threshold voltage of the diode D so that the diode D may be turned on. The voltage difference between the anode and the cathode of the diode D may reach or exceed the threshold voltage of the diode D, thereby turning it on. Accordingly, the VDD voltage may be applied to the gate of the read transistor RT corresponding to the storage node SN, causing the data "1" to be written to the storage node SN of the memory cell MC. The activation of the diode D by the VDD voltage enables data "1" to be stored in the memory cell by switching on the associated read transistor.

In another embodiment, to write data "0" to the memory cell MC, the selected bit line BL may be enabled with a VSS voltage.

Although not shown, after data is written to the memory cell MC, during a hold period for performing a subsequent operation, a level of data stored in the storage node SN may be reduced by a predetermined voltage level.

### Read Operation

Referring to FIGS. 1 and 2, to read the data stored in the memory cell MC, the read word line RWL is enabled to have a VDD voltage level.

If data "1" is to be stored in the memory cell MC, i.e., the read transistor RT is turned on. Accordingly, the VDD voltage transmitted on the read word line RWL may be transferred to the bit line BL, so that the sense amplifier S/A may sense the data "1" stored in the memory cell MC.

On the other hand, if data "0" is to be stored in the memory cell MC, the read transistor RT may be turned off. Accordingly, since no voltage may be provided to the bit line BL, it may be considered that data "0" may be stored in the memory cell MC. The sense amplifier S/A may sense the data "0" stored in the memory cell MC.

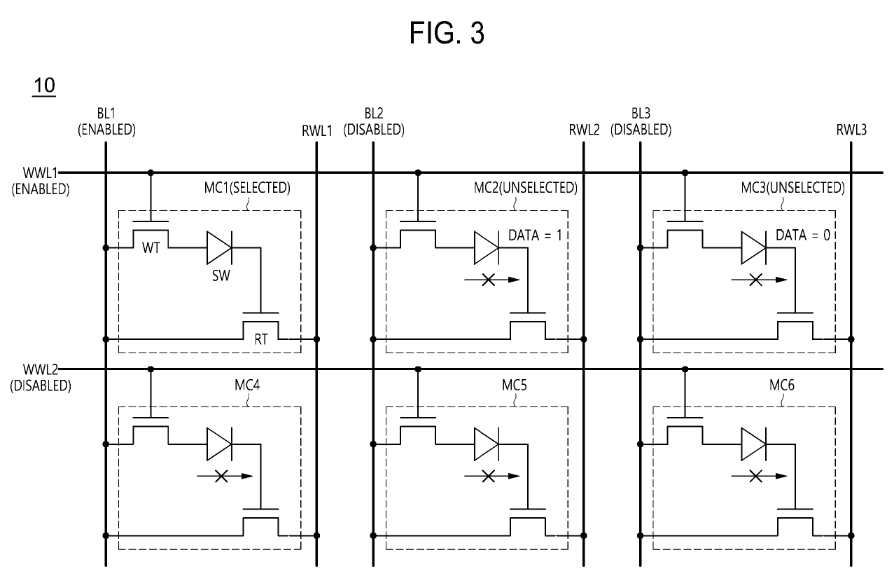

FIG. 3 is a circuit diagram illustrating a semiconductor memory device including memory cells with3-terminals in accordance with embodiments of the present disclosure.

Referring to FIG. 3, a semiconductor memory device 10 may include first and second write word lines WWL1 and WWL2, first to third read word lines RWL1, RWL2 and RWL3, first to third bit lines BL1, BL2 and BL3 and first to six memory cells MC1-MC6.

For example, the first and second write word lines WWL1 and WWL2 may extend parallel to each other along the first direction DR1. The first to third read word lines RWL1-RWL3 and first to third bit lines BL1-BL3 may extend parallel to each other along the second direction which may be perpendicular to the first direction DR1. The first to third read word lines RWL1-RWL3 and the first to third bit lines BL1-BL3 may be arranged alternately.

Each of the first to six memory cells MC1-MC6 may be connected between the first and second write word lines WWL1 and WWL2, the first to third read word lines RWL1, RWL2 and RWL3 and the first to third bit lines BL1, BL2 and BL3. The first to six memory cells MC1-MC6 may be arranged in a matrix form.

According to embodiments of the present disclosure, the first memory cell MC1 may be connected between the first write word line WWL1, the first read word line RWL1 and the first bit line BL1. The second memory cell MC2 may be connected between the first write word line WWL1, the second read word line RWL2 and the second bit line BL2. The third memory cell MC3 may be connected between the first write word line WWL1, the third read word line RWL3 and the third bit line BL3. The fourth memory cell MC4 may be connected between the second write word line WWL2, the first read word line RWL1 and the first bit line BL1. The fifth memory cell MC5 may be connected between the second write word line WWL2, the second read word line RWL2 and the second bit line BL2. The sixth memory cell MC6 may be connected between the second write word line WWL2, the third read word line RWL3 and the third bit line BL3.

Each of the first to six memory cells MC1-MC6 may include a write transistor WT, a read transistor RT and a diode D.

The semiconductor memory device 10 having the above-mentioned structure may be operated as follows.

When writing data "1" to the first memory cell MC1, a logic high voltage may be applied to the first write word line WWL1 to enable the first write word line WWL1 and disable the second write word line WWL2. A write voltage corresponding to data 1 may be applied to the first bit line BL1. The remaining second and third bit lines BL2 and BL3 may be disabled. The first to third read word lines RWL1-RWL3 may also be disabled.

As the first write word line WWL1 and the first bit line BL1 may be enabled, the write transistor WT and the diode D of the first memory cell MC1 may be turned on, so that data “1” may be written in the gate of the read transistor RT.

Even though the first write word line WWL1 may be enabled, the second bit line BL2 and the third bit line BL3 may be disabled, so the second memory cell MC2 and the third memory cell MC3 may be unselected.

According to some embodiments of the present disclosure, if data "1" is to be stored in the second memory cell MC2 before the first memory cell MC1 may be selected, the diode D of the second memory cell MC2 may be turned off even if the first write word line WWL1 may be enabled, since the diode D may have a forward diode structure. Therefore, the second memory cell MC2 may retain the previously written data.

Alternatively, if data "0" may be stored in the third memory cell MC3 before the first memory cell MC1 may be selected, the diode D of the third memory cell MC3 may not be driven even if the first write word line WWL1 may be enabled. Therefore, the third memory cell MC3 may retain the previously written data, i.e., even if the write transistor WT of the third memory cell MC3 may be turned on, both the anode and the cathode of the diode D of the third memory cell MC3 may remain at a low level because the third bit line BL3 may be disabled. Therefore, the diode D of the third memory cell MC3 may be turned off.

Since the second write word line WWL2 is disabled, all of the fourth to sixth memory cells MC4-MC6 connected with the second write word line WWL2 may not be selected.

The read operation may enable the read word line connected with the read target memory cell, as described above. The read transistor RT of the read target memory cell may be turned on based on a gate voltage level of the read transistor RT to transmit the stored data to the bit line.

As such, each of the memory cells with the 3-terminals may include a switch having the forward diode structure. The switch with the forward structure may be connected between the write transistor and the read transistor to improve data retention ability when the memory cell is not to be selected, and to prevent data fluctuation when the adjacent memory cell is to be selected. Furthermore, the memory cell with the 3-terminals may be configured such that the write transistor and the read transistor may be connected in common to one bit line. Accordingly, numbers of bit lines connected to the memory cell may be reduced, thereby reducing an area of the memory cell.

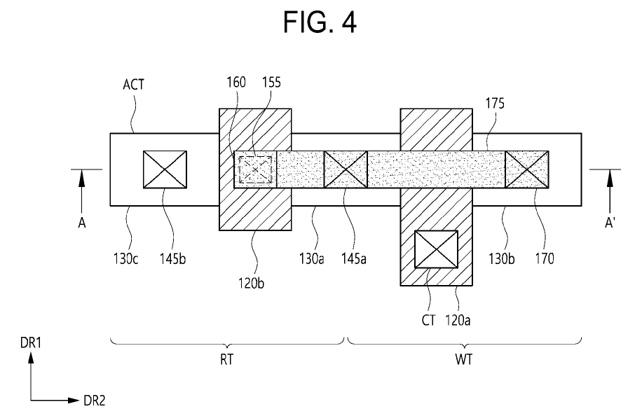

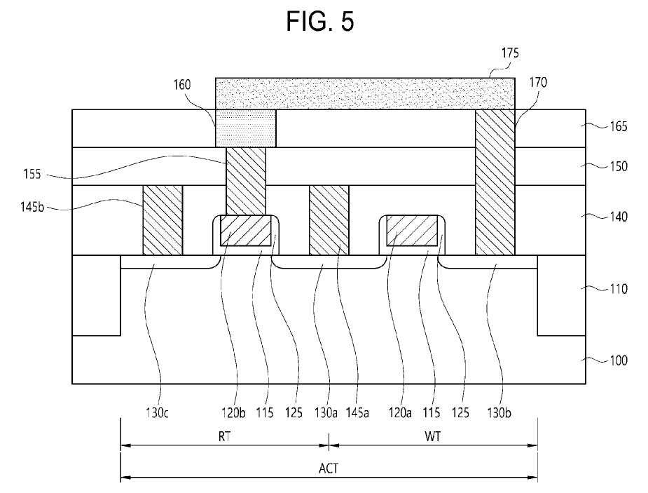

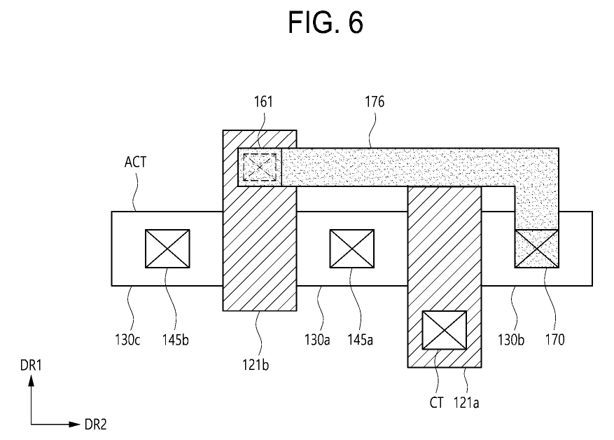

FIG. 4 is a plan view illustrating a 3-terminal memory cell in accordance with some embodiments of the present disclosure. FIG. 5 is a cross-sectional view taken along a line A-A' of FIG. 4. FIG. 6 is a plan view illustrating a 3-terminal memory cell in accordance with some embodiments of the present disclosure.

Referring to FIGS. 4 and 5, a memory cell MC with 3-terminals may be integrated in a bar-shaped active region ACT. The active region ACT may have a short axis parallel to a first direction DR1 and a long axis parallel to a second direction DR2 perpendicular to the first direction DR1. For example, the active region ACT may be located on a semiconductor substrate 100. The active region ACT may be defined by device isolation layer 110 formed in the semiconductor substrate 100. The semiconductor substrate 100 may include a first conductive type impurity, for example, a p-type impurity. Instead of the semiconductor substrate 100, a lower layer including an oxide semiconductor material or a 2D material may be utilized.

A gate 120a of the write transistor WT (hereinafter referred to as the write gate) and a gate 120b of the read transistor RT (hereinafter referred to as the read gate) may be disposed on the active region ACT, respectively. The write gate 120a and the read gate 120b may be spaced apart by a set distance. For example, the write gate 120a and the read gate 120b may each extend parallel to the first direction DR1. The write gate 120a may be a line drawn from a write word line (not shown). For convenience, illustrations of the write word line may be omitted, but it may be located over the write gate 120a. The read gate 120b may be a structure in connection with the diode D, and may be configured in a form of a pattern overlapped with the active region ACT.

The gate insulation layer 115 may be formed between the write gate 120a and the semiconductor substrate 100, and between the read gate 120b and the semiconductor substrate 100, respectively. The gate insulation layer 115 may include, for example, a silicon oxide layer or a high dielectric metal oxide layer. A gate spacer 125 may be formed on a sidewall of each of the write gate 120a and the read gate 120b, respectively. The gate spacers 125 may include, but are not limited to, silicon oxide layers.

The first to third junction regions 130a, 130b and 130c may be formed in the active region ACT between the write gate 120a and the read gate 120b, in the active region ACT corresponding to an outside of the write gate 120a, and in the active region ACT corresponding an outside of the read gate 120b. Thus, the write transistor WT and the read transistor RT may be formed on the active region ACT.

The first to third junction regions 130a, 130b and 130c may include a second conductive type impurity opposite to the first conductive type, for example, an n-type impurity. According to embodiments of the present disclosure, the first junction region 130a may be a common source of the write transistor WT and the read transistor RT. The second junction region 130b may be a drain of the write transistor WT. The third junction region 130c may be a drain of the read transistor RT.

A first insulating interlayer 140 may be formed on the semiconductor substrate 100 on which the write transistor WT and the read transistor RT are formed. First and second contacts 145a and 145b may be formed in the first insulating interlayer 140, respectively. For example, the first contact 145a may be electrically connected to the first junction region 130a. The second contact 145b may be electrically connected with the third junction region 130c corresponding to the source of the read transistor RT.

A bit line (not shown) may be disposed on the first insulating interlayer 140, in contact with the first contact 145a. A read word line (not shown) may be disposed on the first insulating interlayer 140, in contact with the second contact 145b.

In FIGS. 4 and 5, arrangements of the bit lines and the read word lines may be omitted, the bit lines and the read word lines may extend, for example, along the first direction DR1 in FIG. 4. However, the arrangement and position of the bit lines and the word lines may be changed as may be needed in consideration of process technologies.

A second insulating interlayer 150 may be formed on the first insulating interlayer 140 and the bit line. A third contact 155 may penetrate the second and first insulating interlayers 150 and 140 to contact the read gate 120b.

A diode 160 may be formed on the second insulating interlayer 150 to contact the third contact 155. The diode 160 may be configured to include a semiconductor layer including n-type impurities, for example, to form a Schottky diode. In another embodiment, the diode 160 may be configured to include a semiconductor layer including n-type impurities, and a laminated layer of semiconductor layers including p-type impurities, to form a p-n diode. When the diode 160 is a PN diode, the n-type semiconductor layer operating as a cathode may be directly or indirectly connected with the read gate 120b, and the p-type semiconductor layer operating as an anode may be directly or indirectly connected with the drain 130b of the write transistor WT, such that the diode 160 may be operated as a forward diode.

A third insulating interlayer 165 may be formed on the second insulating interlayer 150. The diode 160 may be formed in the third insulating layer 165. The third insulating interlayer 165 may be planarized to expose an upper surface of the diode 160. A lower end of the diode 160 may contact the third contact 155 and an upper end of the diode 160 may contact an interconnection wiring 175.

A fourth contact 170 may be formed in the third, second and first insulating interlayers 165, 150 and 140. The fourth contact 170 may be formed to pass through the third, second and first insulating interlayers 165, 150 and 140 to be electrically connected with the second junction region 130b which corresponds to the drain of the write transistor WT.

In FIG. 5, the first to fourth contacts 145a, 145b, 155 and 170 may be illustrated as a single contact plug extending in a vertical direction, but the embodiments are not limited thereto. For example, the first to fourth contacts 145a, 145b, 155 and 170 may include a plurality of conductive layers, but it is not limited thereto.

The interconnection wiring 175 may be located on the third insulating interlayer 165. The interconnection wiring 175 may electrically connect the diode 160 with the fourth contact 170. For example, the interconnection wiring 175 may electrically connect the diode 160 with a top surface of the fourth contact 170 which is coplanar with the top surface of the third insulating interlayer 165. The interconnection wiring 175 may be formed to overlap the active region ACT, as shown in FIG. 4. Furthermore, in FIG. 4, a reference numeral CT may indicate a contact between the write gate 120aand the write word line WWL.

In another embodiment, as shown in FIG. 6, a diode 161 may be positioned at one end of the read gate 121b withdrawn outwardly of the active region ACT. To connect the diode 161 with the drain of the write transistor WT, i.e., the second junction region 130b, an interconnection wiring 176 may extend to bypass along a periphery of the active region ACT.

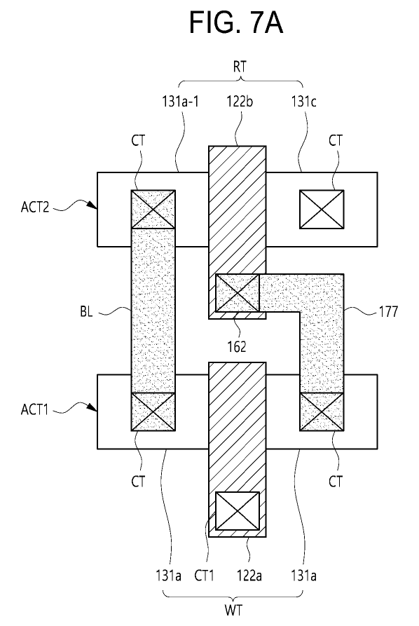

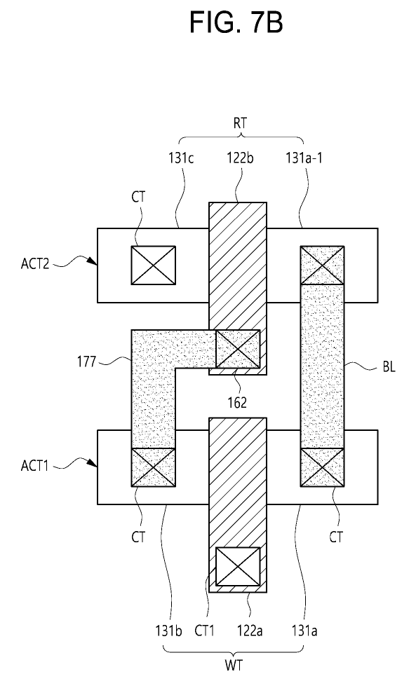

FIGS. 7A and 7B are plan views illustrating a 3-terminal memory cell in accordance with embodiments of the present disclosure.

Referring to FIG. 7A, a memory cell MC with 3-terminals may be integrated in a first active region ACT1 and a second active region ACT2. The first active region ACT1 may be a region where a write transistor WT is formed. The second active region ACT2 may be a region where a read transistor RT is formed. The first and second active regions ACT1 and ACT2 may be arranged to face each other at a set interval. For example, the first and second active regions ACT1 and ACT2 may have the same size, but the embodiments are not limited to this configuration. Furthermore, each of the first and second active regions ACT1 and ACT2 may have a short axis extending in a first direction DR1 and a long axis extending in a second direction DR2 which is perpendicular to the first direction DR2. A difference between the long axis and the short axis of the first and second active regions ACT1 and ACT2 may be less than a difference between the long axis and the short axis of the active region ACT of FIG. 4.

While some embodiments illustrate the first active region ACT1 being positioned in a lower row than the second active region ACT2, the positions of the first active region ACT1 and the second active region ACT2 may be changed as may be needed.

The write gate 122a may be positioned at a center of the first active region ACT1. The read gate 122b may be positioned at a center of the second active region ACT2. The write gate 122a and the read gate 122b may extend along the first direction DR1 perpendicular to the second direction DR2. The write gate 122a and the read gate 122b may be electrically isolated from each other.

A first end of the read gate 122b may be extended over a side of the second active region ACT2 by a predetermined length to be positioned in a gap formed between the first active region ACT1 and the second active region ACT2.

A source 131a of the write transistor WT may be formed in the first active region ACT1 at one side of the write gate 122a. A drain 131b of the write transistor WT may be formed in the first active region ACT1 at the other side of the write gate 122a.

A source 131a-1 of the read transistor RT may be formed in the second active region ACT2 at one side of the read gate 122b. A drain 131c of the read transistor RT may be formed in the second active region ACT2 at the other side of the read gate 122b.

In another embodiment, as shown in FIG. 7B, the source 131a of the write transistor WT may be formed in the first active region ACT1 at the other side of the write gate 122a. The drain 131b of the write transistor WT may be formed in the first active region ACT1 at the first side of the write gate 122a.

The source 131a-1 of the read transistor RT may be formed in the second active region ACT2 at the other side of the read gate 122b. The drain 131c of the read transistor RT may be formed in the second active region ACT2 at the first side of the read gate 122b.

The bit line BL may electrically connect between the source 131a of the write transistor WT and the source 131a-1 of the read transistor RT. The bit line BL may extend, for example, parallel to the first direction DR1. Contacts CT may be interposed between the bit line BL and the source 131a of the write transistor WT, and between the bit line BL and the source 131a-1 of the read transistor RT, respectively.

The diode 162 may be positioned at one end of the read gate 122b. The diode 162 may be electrically connected to the read gate 122b via the contact CT in the gap region between the first and second active regions ACT1 and ACT2.

An interconnection wiring 177 may electrically connect the diode 162 with the drain 131b of the write transistor WT. For example, the contact CT may be positioned between the interconnection wiring 177 and the drain 131b of the write transistor WT to electrically connect the interconnection wiring 177 with the drain 131b of the write transistor WT. In a planar view as illustrated in FIG. 7A the interconnection wiring may have an “L” shape with two substantially linear portions connected together at a right angle to form the “L” shape.

According to some embodiments of the present disclosure, the contact CT may be a vertical connecting structure. A height of the contact CT may be changed in accordance with design specifications.

According to some embodiments of the present disclosure, the memory cell may be coupled to the write word line, the read word line and the common bit line. The memory cell may include the write transistor connected to the write word line and the common bit line, a read transistor connected to the read word line and the common bit line, and a diode connected between the write transistor and the read transistor.

Thus, even if the write transistor and the read transistor may be connected to one common bit line, by forward driving of the diode, the data loss and the fluctuation of the non-selected memory cell may not be generated, so that the area of the memory cell may be reduced while securing the memory characteristics.

The embodiments of the present disclosure have been described in detail with reference to specific embodiments, however the embodiments are not limited to the above embodiments, and are capable of many modifications by those having ordinary skill in the art within the scope of the technical ideas of the present disclosure. Furthermore, the embodiments may be combined to form additional embodiments.

What is claimed is:

1. A memory cell with 3-terminals comprising:
a write transistor connected between a write word line and a bit line;
a diode including an anode in connection with the write transistor; and
a read transistor connected between a read word line and the bit line,
wherein a gate of the read transistor is connected to the diode.

2. The memory cell of claim 1, wherein the write transistor is configured to transmit a write voltage applied to the bit line as data to an anode of the diode in response to an enable signal of the write word line.

3. The memory cell of claim 1, wherein the read transistor is configured to transmit an enable signal of the read word line to the bit line, based on data received from a cathode of the diode.

4. The memory cell of claim 1, wherein the diode is turned on when a voltage level of the anode is no less than a threshold voltage of the diode than a voltage level of the cathode.

5. The memory cell of claim 1, wherein the diode comprises at least one of a Schottky barrier diode and a PN diode.

6. A semiconductor memory device comprising:
a plurality of write word lines extending in parallel in a first direction;
a plurality of read word lines extending parallel along a second direction intersected with the first direction;
a plurality of bit lines extending parallel along the second direction and arranged alternately with the plurality of read word lines; and
a plurality of memory cells, wherein each of the memory cells comprises:
a write transistor connected to one of the plurality of write word lines and to one of the plurality of bit lines;
a diode including an anode in connection with the write transistor; and
a read transistor connected to a cathode of the diode, one of the plurality of read word lines, and the bit line to which the write transistor is connected.

7. The semiconductor memory device of claim 6, wherein the write transistor is configured to transmit a write voltage applied to the bit line as data to an anode of the diode in response to an enable signal of the write word line.

8. The semiconductor memory device of claim 6, wherein the read transistor is configured to transmit an enable signal of the read word line to the bit line, based on data received from the diode.

9. The semiconductor memory device of claim 6, wherein the diode is turned on when a voltage level of the anode is no less than a threshold voltage of the diode than a voltage level of the cathode.

10. The semiconductor memory device of claim 6, wherein the diode comprises at least one of a Schottky barrier diode and a PN diode.

11. A memory cell with 3-terminals comprising:
an active region;
a write transistor and a read transistor integrated in the active region, respectively;
a write word line electrically connected to a gate of the write transistor;
a bit line electrically connected with a source of the write transistor and a source of the read transistor;
a diode positioned over the gate of the read transistor and connected to the gate of the read transistor;
a read word line connected to a drain of the read transistor; and
an interconnection wiring connected between the diode and a drain of the write transistor,
wherein an anode of the diode is connected to the drain of the write transistor and a cathode of the diode is connected to the gate of the read transistor.

12. The memory cell of claim 11,
wherein the active region has a bar shape with a short axis extending in a first direction and a long axis extending in a second direction perpendicular to the first direction,
wherein the gate of the write transistor and the gate of the read transistor extend parallel along the second direction on the active region,
wherein the source of the write transistor and the source of the read transistor include in common a first junction region formed in the active region between the gate of the write transistor and the gate of the read transistor,
wherein the drain of the write transistor includes a second junction region formed in the active region on an outside of the gate of the write transistor, and
wherein the drain of the read transistor includes a third junction region formed in the active region on an outside of the gate of the read transistor.

13. The memory cell of claim 12,
wherein the diode is positioned over the gate of the read transistor overlapping with the active region, and
wherein the interconnection wiring extends to overlap the active region.

14. The memory cell of claim 12,
wherein the diode is positioned over the gate of the read transistor withdrawn outwardly of the active region, and
wherein the interconnection wiring extends to bypass along a periphery of the active region.

15. The memory cell of claim 11, wherein the active region comprises:
a first active region in which the write transistor is integrated; and
a second active region arranged facing the first active region at set intervals, and
wherein the read transistor is integrated in the second active region.

16. The memory cell of claim 15,
wherein the gate of the write transistor is disposed at a center of the first active region, the source of the write transistor is located in the first active region at one side of the gate of the write transistor, and the drain of the write transistor is located in the first active region at the other side of the gate of the write transistor, and
wherein the gate of the read transistor is disposed at a center of the second active region and extends a certain length toward the first active region, the source of the read transistor is disposed in the second active region at one side of the gate of the read transistor, and the drain of the read transistor is disposed in the second active region at the other side of the gate of the read transistor.

17. The memory cell of claim 16,
wherein the diode is positioned at one end of the gate of the read transistor, and
wherein a portion of the interconnection wiring is located between the first active region and the second active region.

18. The memory cell of claim 11, wherein the diode comprises an n-type semiconductor layer.

19. The memory cell of claim 11, wherein the diode comprises a laminated layer of a p-type semiconductor layer and an n-type semiconductor layer.
